(19) United States
(12) Patent Application Publication
(10) Pub. No.: US 2008/0034842 A1
(43) Pub. Date: Feb. 14, 2008

(54) GAS SENSOR USING CARBON NATOTUBES AND METHOD OF MANUFACTURING THE SAME

(75) Inventors: Soo-suk LEE, Yongin-si (KR); Sung-ouk JUNG, Yongin-si (KR); Hun-joo LEE, Yongin-si (KR); In-ho LEE, Yongin-si (KR); Kyu-tae YOO, Yongin-si (KR); Jae-ho KIM, Yongin-si (KR)

Correspondence Address: CANTOR COLBURN, LLP, 55 GRIFFIN ROAD SOUTH, BLOOMFIELD, CT, 06002, US

(73) Assignee: SAMSUNG ELECTRONICS CO., LTD, Suwon-si (JP)

(21) Appl. No.: 11/695,872

(22) Filed: Apr. 3, 2007

(30) Foreign Application Priority Data
Aug. 10, 2006 (KR) 10-2006-0075811

(51) Int. Cl. G01N 27/00; B82B 1/00; B82B 3/00; G01R 3/00

(52) U.S. Cl. 73/31.05; 427/122; 977/957; 73/31.07; 977/891

(57) ABSTRACT

A gas sensor includes a substrate having a plurality of through holes, a pair of electrodes disposed on the substrate, wherein the plurality of through holes are disposed between the pair of electrodes and a plurality of carbon nanotubes covering at least a portion of the plurality of through holes, wherein at least a portion of the plurality of carbon nanotubes is connected with the pair of electrodes.

This application claims priority to Korean Patent Application No. 10-2006-0075811, filed on Aug. 10, 2006, and all the benefits accruing therefrom under 35 U.S.C. §119, the contents of which in its entirety are herein incorporated by reference.

### BACKGROUND OF THE INVENTION

1. Field of the Invention

The present invention relates to a gas sensor which uses carbon natotubes, and more particularly, to a gas sensor which uses carbon natotubes having improved sensitivity and recycle efficiency.

2. Description of the Related Art

While scientific developments have improved the quality of human life, extensive and rapid destruction of nature caused by industrialization and environmental contamination due to increased energy consumption pose a great threat to human beings.

Accordingly, development of a reliable and highly sensitive gas sensor which can detect and quantify different types of harmful gases which cause air contamination is needed. Presently, gas sensors are widely used in various fields such as industries including the manufacturing industry, the agricultural industry, the livestock industry, the office equipment industry, the catering industry, the ventilation industry, the crime prevention industry (e.g., an alcohol level detector), the environment industry (e.g., an air contamination surveillance device and a combustion control device), the disaster prevention industry (e.g., a gas leakage detector, an oxygen deficiency alarm in mines or a fire surveillance device), the medical industry (e.g., a blood gas analysis device or an anesthesia gas analysis device). Applications for gas sensors are expanding every day.

In general, a gas sensor measures the amount of a harmful gas by using the characteristics of a varying electrical conductivity or electrical resistance according to a degree of adsorption of gas molecules by the gas sensor. In the prior art, the gas sensor was manufactured using a metal oxide semiconductor, a solid electrolyte material, or other organic materials. However, the gas sensor which uses the metal oxide semiconductor or the solid electrolyte material starts a sensing operation when the gas sensor is heated to 200 degrees Celsius to 600 degrees Celsius. The gas sensor which uses organic material has a very low electrical conductivity, and the gas sensor which uses carbon black and an organic complex has a very low sensitivity.

Carbon nanotubes (“CNTs”) have recently drawn attention as a new material which can be applied to various industrial fields due to the CNT's high electron emission characteristics and high chemical reactivity. In particular, a CNT is formed of a material which has a very large surface area as compared to the volume of the CNT. Therefore, the CNT is very useful in fields such as detection of minor chemical components and hydrogen storage. A gas sensor, which uses CNTs, detects harmful gases by measuring electrical signals (e.g., conductance or resistance) which vary according to the electron properties of a gas adsorbed onto the CNTs. There are several advantages of using CNTs in gas sensors, including a sensing operation which can start at room temperature, and high sensitivity and high response speeds when harmful gases such as ammonia (“NH₃”) or nitrogen dioxide (“NO₂”) react with the CNTs in the gas sensor, thereby causing the CNTs to have a higher electrical conductivity.

FIG. 1 illustrates a top plan view of a conventional gas sensor of the prior art which uses carbon nanotubes (“CNTs”). FIG. 2 illustrates a cross-sectional view taken along line II-II′ of the conventional gas sensor of the prior art of FIG. 1.

Referring to FIGS. 1 and 2, first and second electrodes 12a and 12b, respectively, are alternately formed on a substrate 10, and carbon nanotubes 20 are coated on the substrate 10, thereby covering the first and second electrodes 12a and 12b, respectively. In the structure of the conventional gas sensor, an electrical signal between the first and second electrodes 12a and 12b, respectively, varies when a specific gas contacts and is adsorbed by the carbon nanotubes 20, thereby detecting the specific gas. However, in the conventional gas sensor described above, the carbon nanotubes 20 are formed on the substrate 10 with a limited surface area exposed to an external environment. Therefore, the surface area of the carbon nanotubes 20 which can react with the gas cannot be maximized, and thus, the sensitivity of the conventional gas sensor cannot be further increased. Also, the gas adsorbed onto the carbon nanotubes 20 must be removed in order to recycle the conventional gas sensor. As such, it is difficult to completely remove the adsorbed gas from the carbon nanotubes 20 formed with a limited surface area exposed to the external environment.

### BRIEF SUMMARY OF THE INVENTION

The present invention provides a gas sensor that has a high sensitivity and a high recycle efficiency.

According to an exemplary embodiment of the present invention, there is provided a gas sensor including a substrate having a plurality of through holes, a pair of electrodes disposed on the substrate, wherein the plurality of through holes are disposed between the pair of electrodes and a plurality of carbon nanotubes covering at least a portion of the plurality of through holes, wherein at least a portion of the plurality of carbon nanotubes is connected with the pair of electrodes.

The plurality of through holes may extend through the substrate in a direction substantially perpendicular to opposing surfaces of the substrate.

The plurality of through holes may extend on the opposing surfaces of the substrate in a direction substantially parallel to the pair of electrodes.

The substrate may be formed of a silicon wafer.

The plurality of through holes may be formed in shapes including a rectangular shape, a circular shape, or a triangular shape.

The pair of electrodes may have an electrical conductivity higher than an electrical conductivity of the substrate.

The pair of electrodes may include gold or titanium.

The pair of electrodes may comprise a first electrode and a second electrode, the first electrode and the second electrode are configured in an interlaced digitated shape alternately formed such that the plurality of through holes interpose a first digit defining the first electrode and an adjacent second digit defining the second electrode.

The plurality of carbon nanotubes may be formed on the substrate to cover at least a portion of the pair of electrodes.

The gas sensor may further include a filter configured to selectively filter a specific gas.

The filter may include silver, iridium, molybdenum, nickel, palladium, platinum, or an alloy of at least one of the foregoing materials.

According to an exemplary embodiment of the present invention, there is provided a method of manufacturing a gas sensor including forming a plurality of through holes on a substrate, disposing a pair of electrodes on the substrate, wherein the plurality of through holes are disposed between the pair of electrodes and forming a plurality of carbon nanotubes covering at least a portion of the plurality of through holes, wherein at least a portion of the plurality of carbon nanotubes is connected with the pair of electrodes.

The forming a plurality of through holes may include forming the plurality of through holes extending through the substrate in a direction substantially perpendicular to opposing surfaces of the substrate.

The forming a plurality of through holes may comprise forming the plurality of through holes extending on the opposing surfaces of the substrate in a direction substantially parallel to the pair of electrodes.

The forming a plurality of carbon nanotubes may comprise forming the carbon nanotubes by a method including a chemical vapor deposition method, a method which uses a carbon nanotube paste, or a Langmuir-Blodgett method.

The method of manufacturing a gas sensor may further include forming the pair of electrodes with a first electrode and a second electrode, the first electrode and the second electrode are configured in an interlaced digitated shape alternately formed such that the plurality of through holes interpose a first digit defining the first electrode and an adjacent second digit defining the second electrode.

The forming a plurality of carbon nanotubes may include forming the plurality of carbon nanotubes to cover at least a portion of the pair of electrodes.

### BRIEF DESCRIPTION OF THE DRAWINGS

The above and other aspects, features and advantages of the present invention will become more apparent by describing in more detail exemplary embodiments thereof with reference to the accompanying drawings, in which:

FIG. 1 illustrates a top plan view of a conventional gas sensor of the prior art which uses carbon nanotubes (“CNTs”);

FIG. 2 illustrates a cross-sectional view taken along line II-II′ of the conventional gas sensor of the prior art of FIG. 1;

FIG. 3 illustrates a top plan view of a gas sensor according to an exemplary embodiment of the present invention;

FIG. 4 illustrates a cross-sectional view taken along line IV-IV′ of the gas sensor of FIG. 3, according to an exemplary embodiment of the present invention;

FIG. 5 illustrates a top perspective view of a substrate of the gas sensor of FIG. 3, according to an exemplary embodiment of the present invention;

FIG. 6 illustrates a front perspective view of electrodes formed on the substrate of the gas sensor of FIG. 5, according to an exemplary embodiment of the present invention;

FIG. 7 illustrates a scanning electron microscope (“SEM”) image of a substrate of a gas sensor according to an exemplary embodiment of the present invention;

FIGS. 8A through 8C illustrate SEM images of carbon nanotubes formed on the substrate of FIG. 7, according to an exemplary embodiment of the present invention;

FIG. 9 is a graph illustrating resistance (Ω) measurement results of a gas sensed by a gas sensor according to an exemplary embodiment of the present invention; and

FIG. 10 is a graph illustrating resistance (Ω) measurement results of a gas sensed by a recycled gas sensor according to an exemplary embodiment of the present invention.

### DETAILED DESCRIPTION OF THE INVENTION

The present invention will now be described more fully with reference to the accompanying drawings, in which exemplary embodiments of the invention are shown.

This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Hereinafter, the present invention will be described in further detail with reference to the accompanying drawings.

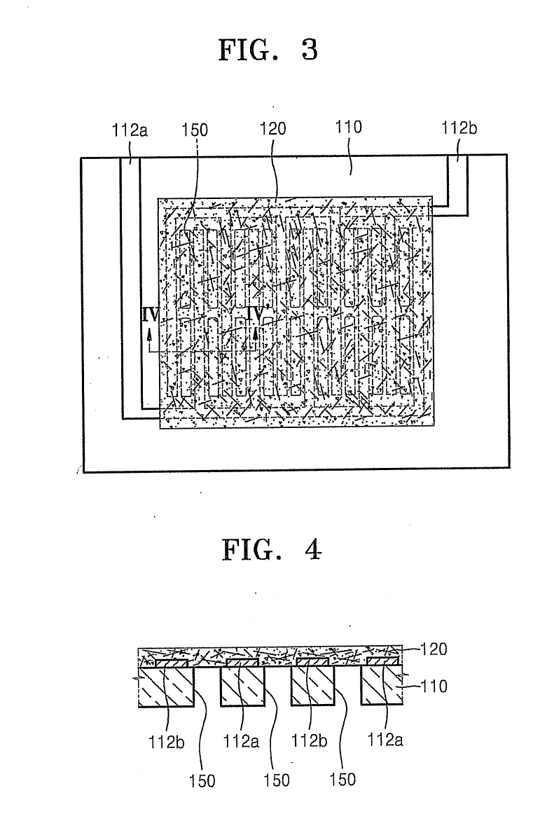

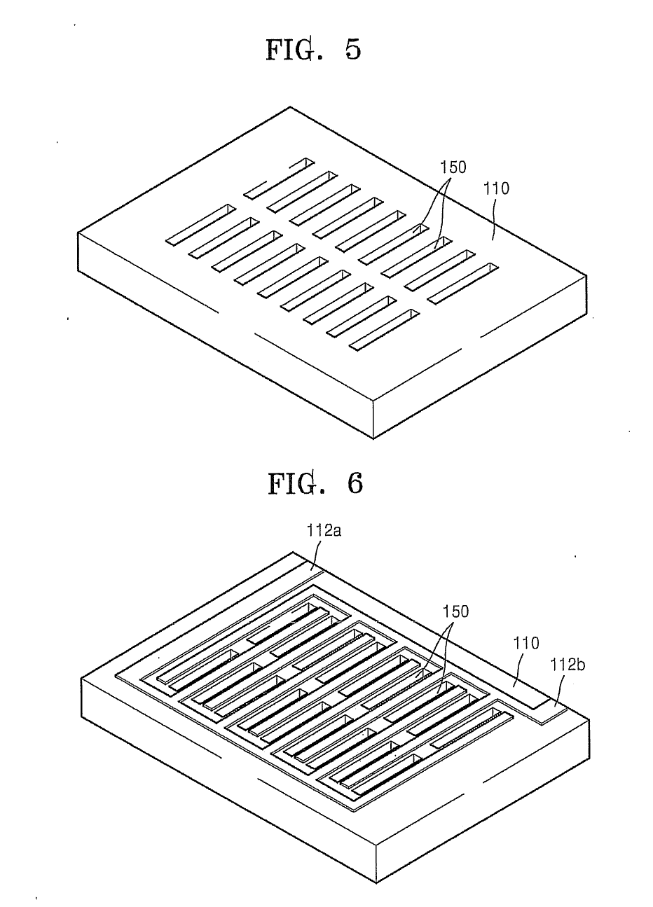

FIG. 3 illustrates a top plan view illustrating a gas sensor according to an exemplary embodiment of the present invention. FIG. 4 illustrates a cross-sectional view taken along line IV-IV′ of the gas sensor of FIG. 3 according to an exemplary embodiment of the present invention, FIG. 5 illustrates a top perspective view of a substrate of the gas sensor of FIG. 3, according to an exemplary embodiment of the present invention and FIG. 6 illustrates a top perspective view of an electrode formed on the substrate of FIG. 5, according to an exemplary embodiment of the present invention.

Referring to FIGS. 3 through 6, electrodes 112a and 112b are formed on a substrate 110, and carbon nanotubes (“CNTs”) 120 are coated on the substrate 110, thereby covering the electrodes 112a and 112b. The substrate 110 may be a silicon wafer.

In the current exemplary embodiment, as depicted in FIG. 5, a plurality of through holes 150 are formed in the substrate 110.

The through holes 150 may be formed by perforating the substrate 110 in a direction substantially perpendicular to an upper surface of the substrate 110, however the through holes 150 are not limited thereto, and may be angled with respect to the upper surface of the substrate 110.

The through holes 150 may be formed to extend relative to opposing surfaces defining the substrate 110 in a direction substantially parallel to the electrodes 112a and 112b.

In FIG. 5, the through holes 150 are arranged in two rows, however the present invention is not limited thereto, that is, the through holes 150 may be formed in a single row or alternatively, in a plurality of rows.

The through holes 150 may be formed in various shapes including a rectangular shape, a circular shape, or a triangular shape, for example, but is not limited thereto.

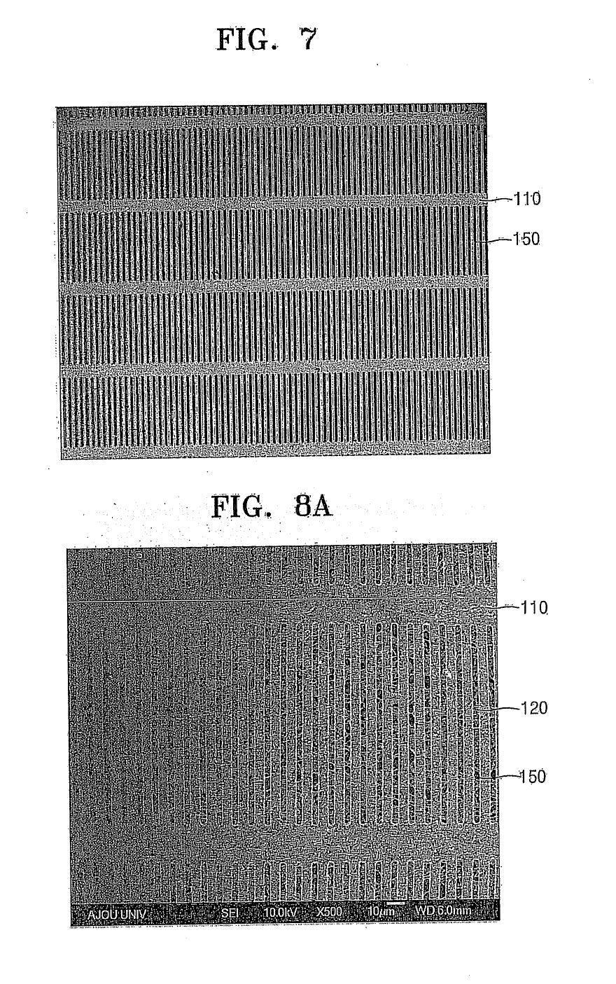

FIG. 7 illustrates a scanning electron microscope (“SEM”) image of a substrate on which through holes 150 of FIG. 6 are formed, according to an exemplary embodiment of the present invention.

As depicted in FIG. 6, the electrodes 112a and 112b are disposed on the substrate 110 on which the through holes 150 are formed. The electrodes 112a and 112b may include a first electrode 112a and a second electrode 112b alternately formed to interpose the through holes 150 therebetween.

The first and second electrodes 112a and 112b, respectively may be formed in an interlaced digitated shape, the first electrode and the second electrode are alternately formed such that the plurality of through holes interpose a first digit defining the first electrode 112a and an adjacent second digit defining the second electrode 112b. The first electrode 112a and the second electrode 112b may be formed in various shapes.

The first and second electrodes 112a and 112b, respectively, may be formed of a material having a high conductivity. Exemplary embodiments of suitable conductive materials may include gold (Au), titanium (Ti), other similar conductive materials and alloys of the foregoing materials.

The CNTs 120 covering the through holes 150 are formed on the substrate 110 between the first and second electrodes 112a and 112b, respectively. In the current exemplary embodiment, the CNTs 120 may be formed to cover at least a portion of each the first and second electrodes 112a and 112b, respectively, disposed on the substrate 110.

The CNTs 120 may be formed using a chemical vapor deposition (“CVD”) method, a method which uses a CNT paste, or a Langmuir-Blodgett (“LB”) method. More specifically, the CNTs 120 may be grown on the substrate 110 using the CVD method or may be formed by coating the CNT paste on the substrate 110.

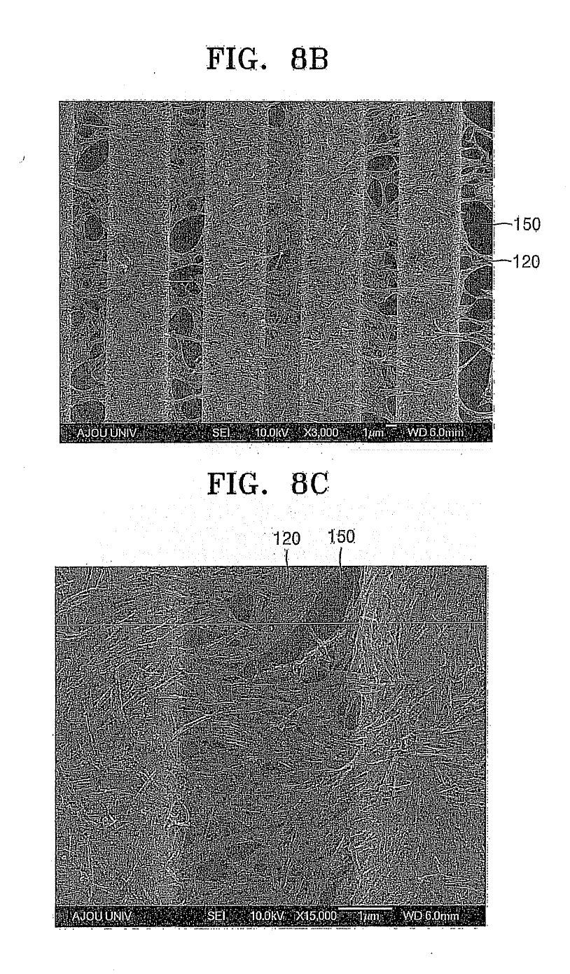

The CNTs 120 may be formed by immersing the substrate 110 into a solution dispersed with CNTs 120 using the LB method, resulting in CNTs 120 as illustrated in FIGS. 8A through 8C. FIGS. 8A through 8C illustrate SEM images of CNTs 120 formed on the substrate 110 using the LB method. The through holes 150 are formed on the substrate 110. FIGS. 8B and 8C illustrate enlarged SEM images of the SEM image of FIG. 8A, according to an exemplary embodiment of the present invention. Referring to FIGS. 8A through 8C, the CNTs 120 are uniformly formed over the through holes 150.

As described above, in the current exemplary embodiment, the CNTs 120 are formed to cover the through holes 150, which are formed to extend through the substrate 110. Therefore, the upper surface of the CNTs 120 and also a lower surface of the CNTs 120 are exposed to an external environment via the through holes 150. Accordingly, when a specific gas contacts the gas sensor according to an exemplary embodiment of the present invention, the specific gas may be adsorbed on the upper surface of the CNTs 120 as well as on the lower surface of the CNTs 120, and also the specific gas may be adsorbed by passing through the CNTs 120. Thus, since the CNTs 120 are formed on the substrate 110 covering the through holes 150, the surface area of the CNTs 120 which is exposed to the external environment is increased which thereby maximizes the surface area of the CNTs which may react with the gas. Accordingly, the sensitivity of the gas sensor may further increase.

The gases adsorbed on the CNTs 120 may be rapidly and effectively removed via the through holes 150, thereby increasing the recycle efficiency of the gas sensor.

The gas sensor as described above may also function as a gas filter if a material (not shown) which may selectively adsorb a specific gas is used on the surface of the CNTs 120. For example, a gas which is composed of dichloroethylene, acetic acid, or propanoic acid may be adsorbed by silver (Ag), and a gas which is composed of ethylene, benzene, or cyclohexane may be adsorbed by iridium (Ir). Also, a gas which is composed of methane or formic acid may be adsorbed by molybdenum (Mo), and a gas which is composed of methane, methanol, or benzene may be adsorbed by nickel (Ni). Furthermore, a gas which is composed of benezene, acetylene, ethylene, methanol, benzene and carbon monoxide (“CO”), or methane may be adsorbed by palladium (Pd), and a gas which is composed of aniline, ammonia, cyanobenzene, m-xylene, naphthalene, N-butylbenzene, or acetonitrile may be adsorbed by platinum (Pt). Accordingly, exemplary embodiments of the material may include silver (Ag), iridium (Ir), molybdenum (Mo), nickel (Ni), palladium (Pd) or platinum (Pt). In alternative exemplary embodiments, the material may further include other metals which have adsorption selectivity with respect to a specific gas.

FIG. 9 is a graph illustrating the measurement results of sensing a gas using a gas sensor according to an exemplary embodiment of the present invention. FIG. 9 illustrates measurement results in terms of a resistance (Ω) of a gas sensor according to an exemplary embodiment of the present invention when 2.5 parts per million (“ppm”) of nitrogen dioxide (“NO₂”) was injected as a measuring gas. The conductance variation (“ΔG”) of the gas sensor was calculated using the results depicted in FIG. 9 and by the equation (ΔG=(Gᵢ−G₀)/G₀). In the conductance variation equation, Gᵢ refers to a conductance after the gas was injected, and G₀ refers to an initial conductance before gas injection.

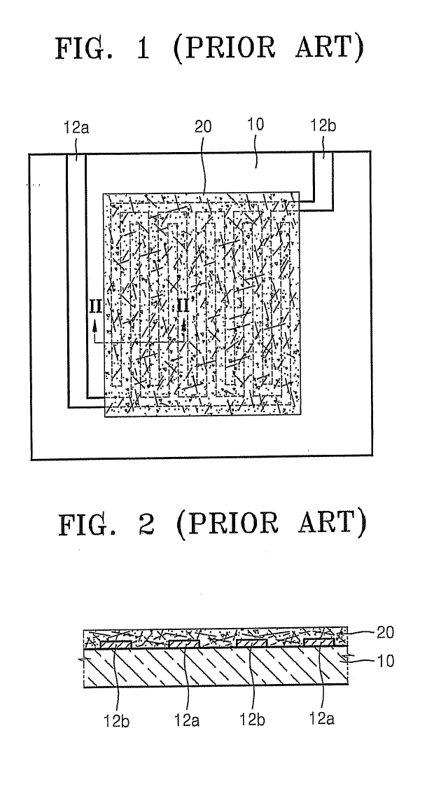

The gas sensor according to an exemplary embodiment of the present invention resulted in a conductance variation (“ΔG”) of approximately 1.11. However, the conventional gas sensor of the prior art depicted in FIG. 1 resulted in a conductance variation (“ΔG”) of only approximately 0.80. Based on the results, it can be seen that the gas sensor according to an exemplary embodiment of the present invention results in a sensitivity improvement of 39 percent as compared to a conventional gas sensor of the prior art.

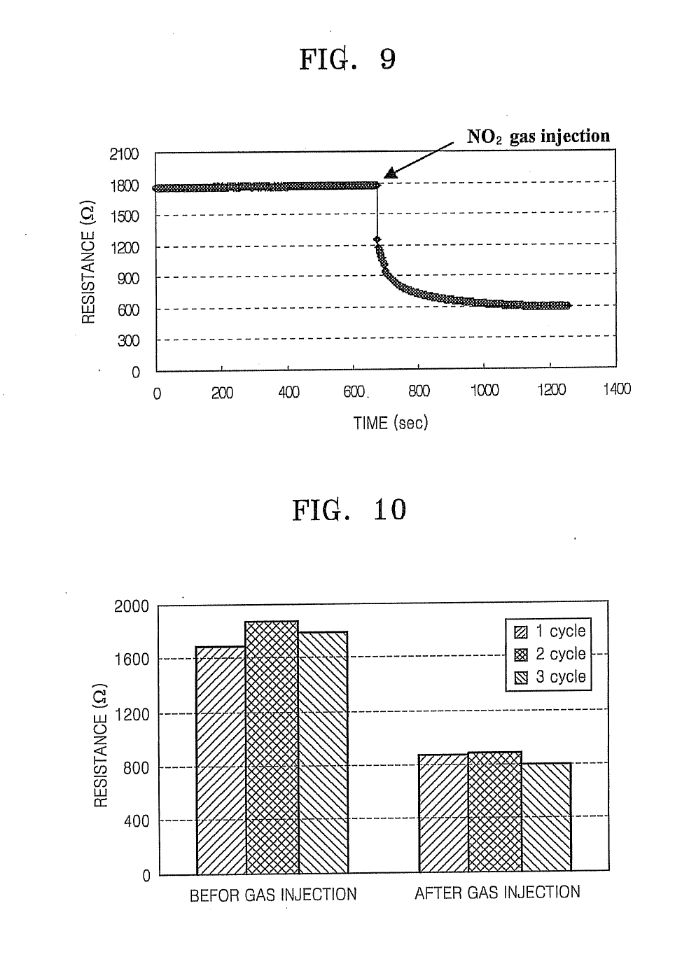

FIG. 10 is a graph illustrating the measurement results of a recycled gas sensor according to an exemplary embodiment of the present invention. FIG. 10 illustrates the measurement results of a gas sensor recycled three times using 2.5 parts per million (“ppm”) of NO₂ gas. To recycle the gas sensor, ultraviolet rays were irradiated on the gas sensor and nitrogen (N₂) gas was introduced. Referring to FIG. 10, the gas sensor had nearly the same resistance in each cycle before the gas was injected, and also had nearly the same resistance in each cycle after the gas was injected. From the results, it can be seen that the gas sensor according to an exemplary embodiment of the present invention has a very high recycle efficiency.

As described above, the exposed surface area of CNTs may be maximized by forming CNTs on a substrate in which a plurality of through holes are formed. Therefore, the sensitivity of the gas sensor may significantly increase. Also, the CNTs on which gases are adsorbed may be rapidly and effectively removed from the substrate via the through holes formed in the substrate, thereby increasing the recycle efficiency of the gas sensor.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A gas sensor comprising:
a substrate having a plurality of through holes;
a pair of electrodes disposed on the substrate, wherein the plurality of through holes are disposed between the pair of electrodes; and
a plurality of carbon nanotubes covering at least a portion of the plurality of through holes, wherein at least a portion of the plurality of carbon nanotubes is connected with the pair of electrodes.

2. The gas sensor of claim 1, wherein the plurality of through holes extend through the substrate in a direction substantially perpendicular to opposing surfaces of the substrate.

3. The gas sensor of claim 2, wherein the plurality of through holes extend on the opposing surfaces of the substrate in a direction substantially parallel to the pair of electrodes.

4. The gas sensor of claim 1, wherein the substrate is a silicon wafer.

5. The gas sensor of claim 1, wherein the plurality of through holes are formed in shapes including a rectangular shape, a circular shape, or a triangular shape.

6. The gas sensor of claim 1, wherein the pair of electrodes have an electrical conductivity higher than an electrical conductivity of the substrate.

7. The gas sensor of claim 6, wherein the pair of electrodes include gold or titanium.

8. The gas sensor of claim 1, wherein the pair of electrodes comprise a first electrode and a second electrode, the first electrode and the second electrode are configured in an interlaced digitated shape alternately formed such that the plurality of through holes interpose a first digit defining the first electrode and an adjacent second digit defining the second electrode.

9. The gas sensor of claim 1, wherein the plurality of carbon nanotubes are formed on the substrate to cover at least a portion of the pair of electrodes.

10. The gas sensor of claim 1, further comprising a filter configured to selectively filter a specific gas.

11. The gas sensor of claim 10, wherein the filter includes silver, iridium, molybdenum, nickel, palladium, platinum, or an alloy of at least one of the foregoing materials.

12. A method of manufacturing a gas sensor, the method comprising:
forming a plurality of through holes on a substrate;
disposing a pair of electrodes on the substrate, wherein the plurality of through holes are disposed between the pair of electrodes; and
forming a plurality of carbon nanotubes covering at least a portion of the plurality of through holes, wherein at least a portion of the plurality of carbon nanotubes is connected with the pair of electrodes.

13. The method of claim 12, wherein the forming a plurality of through holes comprises forming the plurality of through holes extending through the substrate in a direction substantially perpendicular to opposing surfaces of the substrate.

14. The method of claim 12, wherein the forming a plurality of through holes comprises forming the plurality of through holes extending on the opposing surfaces of the substrate in a direction substantially parallel to the pair of electrodes.

15. The method of claim 12, wherein the forming a plurality of carbon nanotubes comprises forming the carbon nanotubes by a method including a chemical vapor deposition method, a method which uses a carbon nanotube paste, or a Langmuir-Blodgett method.

16. The method of claim 12, further comprising forming the pair of electrodes with an electrical conductivity higher than an electrical conductivity of the substrate.

17. The method of claim 12, further comprising forming the pair of electrodes with a first electrode and a second electrode, the first electrode and the second electrode are configured in an interlaced digitated shape alternately formed such that the plurality of through holes interpose a first digit defining the first electrode and an adjacent second digit defining the second electrode.

18. The method of claim 12, wherein the forming a plurality of carbon nanotubes includes forming the plurality of carbon nanotubes to cover at least a portion of the pair of electrodes.
